(19) United States
(12) Patent Application Publication
(10) Pub. No.: US 2009/0314051 A1
(43) Pub. Date: Dec. 24, 2009

(54) METHOD FOR DETERMINATION OF ELECTRICAL PROPERTIES OF ELECTRONIC COMPONETS AND METHOD FOR CALIBRATION OF A MEASURING UNIT

(75) Inventors: Victar KHUTKO, Dresden (DE); Andrej RUMIANTSEV, Dresden (DE); Stojan KANEV, Thiendorf OT Sacka (DE)

Correspondence Address: HESLIN ROTHENBERG FARLEY & MESITI PC, 5 COLUMBIA CIRCLE, ALBANY, NY, 12203, US

(73) Assignee: SUSS MICROTEC TEST SYSTEMS GMBH, Sacka (DE)

(21) Appl. No.: 12/488,702

(22) Filed: Jun. 22, 2009

(30) Foreign Application Priority Data
Jun. 20, 2008 (DE) 10 2008 028 991.4

(51) Int. Cl. G01D 18/00; G01R 19/00

(52) U.S. Cl. 73/1.01; 324/76.11

(57) ABSTRACT

In a method for calibration of a measurement unit for determination of electrical properties of electronic components using at least one planar calibration standard, an electrical measurement quantity is measured at two different temperatures. The electrical property of the calibration standard is known at at least one temperature or is to be determined by calculation. A temperature coefficient is determined from both measured quantities, which describes the relative change of the electrical property of the calibration standard accompanying the temperature change and with which the electrical property of the calibration standard is determined at a measurement temperature. From the change in electrical property, an error coefficient of the measurement unit is determined. A method is also provided for determination of an electrical property of an electronic component, using the calibration method.

### CROSS REFERENCE TO RELATED APPLICATIONS

This application claims priority of German application No. 10 2008 028 991.4 filed on Jun. 20, 2008, the entire contents of which is hereby incorporated by reference herein.

### TECHNICAL FIELD

The invention generally concerns determination of electrical properties of electrical components by means of probers. It especially concerns a method for temperature-dependent calibration of the measurement unit which is part of such a prober for determination of such properties, using planar calibration standards for the high-frequency and low-frequency range, which are contacted by means of test probes. The invention also concerns a method for determination of a temperature-dependent electrical property, using the calibration method.

### PRIOR ART

For characterization and modeling of electronic components, their measurement occurs in appropriate test devices, so-called test stations or probers. The contact islands of the components being measured are contacted for measurement by means of contact arrangements in the form of test probes, and electrical signals are supplied and/or tapped. Very different requirements are imposed on the test devices, depending on the electronic component being measured and especially the frequency range relevant for the component, i.e., the high- or low-frequency range.

In the high-frequency (HF) range, whose lower limit is constantly being shifted to higher frequencies with the development of electronic components and which now lies at frequencies from about 6 GHz, the test device includes a vectorial network analyzer (VNA) as measurement unit. Vectorial network analyzers serve for precise measurement of electronic elements and components as well as active and passive high-frequency circuits and high-frequency assemblies up to antennas.

The form of description of electrical behavior of electronic elements and components common in high-frequency technology occurs via their scatter parameters (also S parameters). They do not link currents and voltages but wave quantities. This representation is particularly adapted to physical circumstances. A so-called system error correction ensures that precise measurements of the scatter parameters of the components can be performed with vectorial network analyzers. This system error correction requires precise calibration measurement of standards whose electronic behavior is known or can be determined in the context of system error correction.

For calibration of a network analyzer having n measurement gates, reflection and transmission parameters of different n-gate calibration standards connected in arbitrary sequence between the measurement gates, which have no transmission, and different two-gate calibration standards connected between the measurement gates in defined combination and sequence, which all have a transmission path, are measured. Using the measured calibration standards and by computer determination of error-corrected scatter matrices (Sx) of the calibration standards from the error coefficients of each two-gate calibration standard, the error coefficients of the network analyzer are calculated by means of an appropriate method.

With these correction data and a corresponding correction calculation, the measured values are obtained for each arbitrary measured object, which are freed of system errors of the network analyzer and the feed lines, for example, couplings (crosstalk) or mismatching (reflections). Precise calibration is therefore decisive for measurement, characterization and modeling of electronic components.

In the LF frequency range in which signals into the 3 GHz range, now maximum 6 GHz, are used with increasing scaling of components and lower power consumption, measurement methods are used based on measurements of capacitances, voltages and inductances in this frequency range. Thus, for characterization of electronic components their current-voltage characteristic is determined by pulse I/V measurement, or their capacitance-voltage characteristic (CV measurements) is determined to determine charge carrier profiles.

Distinctly lower power measurement signals are used in these measurements than for the measurements that were common even a few years ago, since even a low power can lead to destruction of the component or unusable measured values. Thus, pulsed resistance and pulsed I/V measurements occur with pulses of only 50 microseconds, even at low currents, since short pulses mean that less power is taken up by the electronic component. Determination of low-frequency noise (LFN), for example, by 1/f measurement, serves to characterize the components and occurs at the smallest measurement signals in the aforementioned frequency band.

Because of the signal quantities and frequency ranges, parasitic effects from external electromagnetic fields and those generated by the measurement itself gain significance. For example, DC offsets and network frequency disturbances must be avoided during sensitive pulse measurements. To limit these effects, measurement occurs in a shielded environment or shielding housings.

The precision of calibration and its transferability to the actual measurement environment also have an effect on the measurements. The calibration measurements now common for component characterization in the mentioned frequency range, however, only consider the measurement instruments. Here again, however, it is essential to position the calibration plane, as is known from scatter parameter measurement, up to the inputs and outputs of the component, i.e., up to the test probes contacting the component.

Because of the losses occurring in the corresponding frequency signals and influencing of the measurement by disturbance signals, which are sometimes on the same order of magnitude as the measurement signals, the required values are not reached with respect to measurement resolution and measurement accuracy.

The effect of climatic conditions on the measurement of the calibration standards and the electronic components must also be considered, especially at a measurement temperature deviating from room temperature. Because of the temperature dependence of the impedances and the losses both of the calibration standards and the components, the temperature dependence must also be taken into account in addition to the frequency dependence of their electrical properties.

Present calibration measurements are conducted both in the HF and LF range with calibration standards that are measured at room temperature. Calibration standards can therefore be used, whose electrical behavior is known but consideration of the actual thermal conditions of the component is not possible. It is often essential for characterization of components to also set extreme climatic conditions under which the components will later be used. In order to be able to conduct a calibration, the calibration standards are now decoupled thermally from the component being measured in a direct temporal and spatial context. Such thermal decoupling can be readily achieved for the holding device, but not for the test probes, which in this case act as heat carriers between the component and the calibration standard and have a thermal effect that cannot be ignored because of the size and weight ratios.

It must also be kept in mind both for HF and LF measurement that the measurement of electronic components in the wafer structure (on-wafer measurement) is subject to special boundary conditions, especially with respect to performability of the calibration standards. In the semiconductor field it is desirable that the user implement the calibration standards on the wafers themselves. The geometric reproducibility and equivalence of calibration standards produced in this way is very high. However, the electrical properties are only achieved in good approximation.

Thus, the reflection standard no-load, for example, varies very strongly from the scatter parameter measurement with respect to its dc resistance values. However, it is then advantageous that the calibration standards are situated on the same substrate support (semiconductor) as the measured objects. In addition to the advantages of low travel paths, parasitic elements as well as transition effects from the test probe to the wafer can also be “calibrated out.”

Calibration methods on a wafer are now known, which determine the scatter parameters with sufficient accuracy, using known and sometimes also unknown calibration standards and in the latter case using a so-called self-calibration of the unknown standards, and then differences in the measurement environment are implemented, for example, by means of so-called de-embedding and differences in the calibration environment, like the substrate on which the calibration standards and their components are implemented, and the design of the components, the specific employed materials of the metallization on the wafer and others are mathematically considered by the calibration method itself. A method for error correction of calibration methods is known as de-embedding, in which the scatter parameters obtained according to a first calibration and still not sufficiently cleared of errors is subjected to a second measured value correction.

The calibration standards for low-frequency component characterization are now mostly produced on separate calibration substrates so that their physical reproducibility is readily controlled, but parameters of a varying measurement environment often cannot be considered in the required timeframe.

### BRIEF PRESENTATION OF THE INVENTION

With the proposed calibration method and the measurement method using the calibration method for determination of electrical properties of electronic components, the so-called devices under test (DUTs), it is possible to determine the properties under thermal conditions to which the DUTs are exposed during application. Calibration occurs in the corresponding thermal measurement environment at which the electrical properties of the DUT are also determined. All changes of the measurement system accompanied by a temperature change are included, for example, the varying electrical and magnetic properties of the dielectric substrates that have a direct effect on the physical values of the calibration standards formed on it. In comparable fashion other climatic changes in the measurement environment, like pressure, moisture content, composition of the surrounding atmosphere or others can also be considered.

Electrical property here should be understood to mean a property that describes the behavior of a DUT in the different frequency ranges. As explained above, in the high-frequency range these are the scatter parameters and in the low-frequency range especially impedances, resistances, voltages, capacitances and/or inductances for characterization of the noise behavior, for determination of the current-voltage characteristic or the capacitance-voltage characteristic. In order to determine these properties one skilled in the art is familiar with the required electrical measured quantities, depending on the electrical property being determined, in which the mentioned properties correspond to the measured quantities for the LF range. The electrical measured quantities are measured both on the calibration standard and on the DUT.

The mentioned calibration methods can also be used both in the high-frequency and low-frequency range and also use of unknown calibration standards, utilizing the known methods for self-calibration for calibration of vectorial network analyzers (VNA).

In the first place this supports the use of calibration substrates with absolutely or relatively precisely adjustable, known or unknown electrical properties of the calibration standard. In the second place, it is also possible to use calibration standards, which are prepared by the user himself on the substrate, which also carries the DUT, for example, the wafer or other, also dielectric support substrates. These so-called wafer-embedded calibration standards, in contrast to the prior art, are usable for all standards from the LF range, for example, for capacitance or resistance structures.

Calibration occurs with the described method both for the HF and LF range up to the end of the test probe so that the measurement plane is positioned up to the inputs and outputs of the DUT.

### DETAILED DESCRIPTION OF THE INVENTION

The invention will be explained below on practical examples, in which the inventions are to be considered only as an illustrative explanation and not as restrictive.

Initially the invention will be explained with reference to the description of calibration of the network analyzer and determination of the scatter parameters of an HF component.

For temperature-dependent calibration of a network analyzer the scatter parameter Sᵢⱼ of the known and possibly also unknown calibration standard being measured for the employed calibration method is initially determined at a first temperature T₁. Which calibration standards, which number and which of them must actually be known depends on the employed calibration method and this again on the implementability of known calibration standards, among other things. This first measurement should also be referred to as reference measurement. The first temperature T₁ will generally be room temperature, since the electrical properties of the calibration standards are known here or can at least be determined by calculation by self-calibration.

In a second step the scatter parameters Sᵢⱼ′ of the same calibration standards are determined at at least a second temperature T₂ with the largest possible temperature difference between T₁ and T₂ relative to the scatter parameters Sᵢⱼ of the reference measurement. This occurs by determining the deviation of scatter parameter |Sᵢⱼ-Sᵢⱼ′| during the second measurement in comparison with the first measurement, in which ij is an element of the set {11, 12, 13, 21, 22, . . . , nn}, for reflection and transmission of a wave running to the n-gate-measured object and back again.

A temperature coefficient is calculated from the determined deviations. By means of the temperature coefficient, the scatter parameters determined at a subsequent temperature referred to as measurement temperature for calibration of the VNA are converted to the temperature at which an electronic component is to be measured. By means of these corrected scatter parameters, the error coefficients of the network analyzer are determined by calculation, using the method linked to the selected calibration method, for example, 7- or 10-term method.

Since only the relative changes of the scatter parameters and not the scatter parameters themselves are determined for determination of the temperature coefficient and the resulting error coefficient of the measurement unit, this method permits use of both known and unknown calibration standards and therefore also standards that are produced on the wafer. The temperature model, once determined for the calibration standards, is applicable to any of the known calibration methods, for example, both to SOLT or TRL and also LRM, RRMT or others, in which the letter combination of the method name states the employed calibration standards.

An error correction of the temperature model by de-embedding is also not necessary. Consideration of the temperature drift of the measured arrangement can be included by means of the known method described in “Proposed procedures for verifying probe station integrity and on-wafer measurement accuracy”, NIST/Industrial MMIC Consortium.

If in one embodiment of the method the two calibration measurements, the reference calibration and the tested calibration, are conducted at the beginning and end of experiment under varying climatic conditions, the system drift can be quantitatively determined under these changes. In the ideal case both methods can lead to the same results so that the deviation is zero.

The temperature coefficient in other embodiments of the method can also be conducted by means of more than two measurements at different temperatures. In addition, small temperature differences between T₁ and T₂ can also be used. The temperature coefficient can be either a constant value, a function or a specific data set of temperature-related values corresponding to the chosen measurement points and number of measurements.

In order to be able to determine effects of the substrate or the employed HF measurement tips, the temperature-dependent measurements and the relative changes must also be determined for standards on different substrates and with measurement probes deviating from each other in structure and material.

Since, as explained above, the electrical properties of the calibration standards of the DUTs are frequency-dependent, in other embodiments of the method the measurements can be conducted at different frequencies in order to determine a frequency-dependent temperature coefficient. It was found that the deviations that occur during a certain temperature change increase with increasing frequency. Based on the frequency-dependent temperature coefficients, the electrical properties of an electronic component can also be determined in frequency-dependent fashion.

The aforementioned descriptions of the calibration method and its different embodiments initially refer to measurements in the HF range.

However, the temperature coefficients in the LF range are also to be determined in comparable fashion in order to carry out the aforementioned different characteristics for characterization of LF components and assemblies. The essential process explained above for calibration also applies for calibration in the LF range as to how the electrical properties being determined and the corresponding electrical measurement quantities are to be assigned to the LF range and how the required calibration standards are to be measured for this purpose. The calibration method in this frequency range only differs from the calibration method described above in the HF range in that only known calibration standards are used, i.e., known at the first temperature. For this reason other appropriate methods for determination of the error coefficients of the measurement unit from the temperature-corrected electrical property are usable and known.

The type of usable calibration standards depends in particular on the measurement method. For example, for CV measurements impedances with different cutoffs, similar to a wave cutoff of 50 Ω or a short circuit or no-load, are used. In addition, a low-loss capacitor is used. The latter can be formed, for example, by a long coplanar wave guide or have more complex structures, for example, two opposite comb structures in order to achieve a higher precision at the set capacitance of the calibration standard.

Different resistors are required as calibration standard for the I/V measurements. Calibration standards, like those used for impedances described above for CV measurement or standards known from determination of scatter parameters of electronic components or thin-film resistors, are often used for calibration for LFN measurements.

Due to the essential equivalents of calibration methods in the HF and LF range, the described embodiments are also applicable to calibration in the LF range. Both can also be combined with each other in a test arrangement. So-called source monitor units (SMUs), also referred to as source measurement units, which can be programmable, can be used for I/V characterization of calibration standards and DUTs. An SMU is a precise network part that permits voltage supply and measurement with a resolution of 1 mV or less, as well as current supply and measurement with a resolution of 1 μA or less. A precise resistance measurement is continuously possible by means of the SMU, as well as a combination with the test arrangement having a vectorial network analyzer. In the latter case calibrations in measurements of DUTs over the entire frequency range and the temperature range of interest can be conducted with a test arrangement if the HF and LF calibration standards are provided, for example, on a calibration substrate.

The calibration standards for HF and LF measurements are planar lines on a support substrate in which their exact physical design for reproducible electrical properties, especially with known or precisely determinable impedance, is possible. By changing the physical parameters, like the length, the calibration standards can also be made trimmable, i.e., adjustable to a specific electrical property value. Different embodiments of the arrangement of ground and signal lines are generally described as planar lines. One embodiment in planar lines are the coplanar lines. The ground and signal lines in them lie on a plane. On the other hand, in so-called microstrip or mixed arrangements the ground and signal lines lie one above the other in two planes electrically insulated from each other.

Different dielectric, for example, ceramic or also semiconducting substrates, are used as calibration substrate, in which the substrate can be adapted to the support substrate of the electronic component because of the effect of the substrate on different measurements or the wafer with the components itself serves as support substrate.

The calibration substrate is generally arranged in the vicinity of the electronic component being measured in order to reduce the effect of the measurement surroundings in the first place, and secondly to use the same measurement arrangement for calibration and measurement up to the contact fingers and thus be able to implement the calibration plane displaced relative to the component.

To determine an electrical property of a DUT, a calibration is initially conducted on an appropriate test device with determination of a temperature coefficient, optionally frequency-dependent, according to one of the methods described above.

For this purpose one or more DUTs which are situated in the wafer composite or arranged on the support substrate, as well as one or more calibration standards, are arranged on a holding device. The calibration standards can be formed on the wafer or arranged on the support substrate. As an alternative, a separate calibration substrate also held by the holding device has a calibration standard.

The generally several test probes are held in a relative position to each other by a probe holder so that several contact surfaces can be contacted simultaneously. For a better overview the following process will be explained on the example of an individual calibration standard and only one DUT. Contacting and measurement of additional calibration standards in succession or simultaneously with a corresponding arrangement of a number of test probes or scanning of all DUTs of a wafer occurs similarly.

By means of an appropriate positioning device the calibration substrate and the test probes are initially positioned relative to each other, both moved toward each other to produce reliable electrical contact and the calibration measurement then occurs. For this purpose the calibration standard is supplied a signal and the signal generated by this or the signal modified by the calibration standard is tapped by the test probes and fed to the measurement unit for processing.

This first measurement occurs at temperature T₁, for example, at room temperature. After setting a second temperature T₂, for example, 100° C., an additional measurement of the calibration standard occurs. In the same manner additional measurements can occur at temperatures T₃ and T₄, for example, 50° C. and 200° C. A temperature coefficient is determined from these measurements as described above.

The temperature is then set at the measurement temperature T_{M} at which a DUT is to be measured, for example, 150° C. or 250° C., and measurement of the calibration standard is repeated. With reference to measured values at T₁ and T₂, measured or electrical properties derived from them can be predicted by using the temperature coefficients, which are compared with the measured values or derived properties in order to determine an error coefficient from this comparison. This error coefficient serves to compensate the measured quantity or electrical property of a DUT in order to clear it of system errors.

The desired measured quantity or electrical property of the DUT is determined by an additional measurement at the measurement temperature T_{M} by carrying this out with the existing test arrangement after producing electrical contact of the test probes with the DUT as described above for calibration. With reference to performance of the measurement the explanations on calibration measurement are referred to. The following clearing of the measured quantity by using the error coefficient occurs according to known methods. This is often already implemented in the measurement unit, for example, the vectorial network analyzer.

If the prevailing measurement environment is reproducible or a change or drift is known so that the calibration values can be reused, these can be entered in a database in order to be available for additional later measurements. Electronic components, which were produced for test purposes and whose electrical properties were determined very precisely, can be used for calibration measurements from their development. The later measurements can occur at any measurement temperatures and, if the temperature coefficient was determined in frequency-dependent fashion, also at any frequencies. The previously determined, also frequency-dependent deviations of the electrical properties are entered as error coefficients in the form of specific values or as a function in a measurement unit, for example, a vectorial network analyzer, and used directly during the calibration method for calculation of electrical properties.

According to different embodiments of the method the calibration standards can be arranged either on the test substrate on which a DUT being tested is also arranged, or on a separate calibration substrate.

Separate calibration substrates are advantageous if very precise trimmed standards are desired or if the substrates can be used again, for example, for further measurements of DUTs. The material of the calibration substrate can then also deviate from that of the test substrate if the effect of the substrate on the error coefficient to be determined in the calibration was determined beforehand as described above with reference to different substrates.

If the calibration standards are formed on the test substrate, for example, by the producer of the electronic component itself, the standards in comparison with standards on calibration substrates often have greater deviations from the electrical property being adjusted. As explained above, this deviation is unharmful, since it is calibrated out by the calibration method. Such an arrangement makes an almost consistent measurement environment available for calibration standard and DUT. The electrical properties of the calibration standard are also to be determined in the course of measurement of several DUTs, so-called on-the-fly, for example, by means of the aforementioned SMU.

Such on-the-fly calibration measurements, which would be required for continuous implementation of different changes in the measurement environment and are conducted as an intermediate step between two consecutive measurements to track the calibration, are naturally also possible with calibration substrates. For this case a calibration substrate is kept ready on the holding device, which also holds the test substrate and optionally has a separate component configured for the calibration substrate, in addition to the test substrate, so that an immediate and unhampered change of the contacts of the test probe arrangement is possible between the DUT and the calibration standard.

We claim:

1. A method for calibration of a measurement unit for determination of electrical properties of electrical components, comprising the following steps:
preparing at least one planar calibration standard;
producing a single path on such calibration standard by electrical contacting;
obtaining a first measurement of an electrical measured quantity of the calibration standard at a first temperature, at which an electrical property of the calibration standard is known or to be determined by calculation, to determine an electrical property of the calibration standard;
obtaining a second measurement of the same electrical measured quantity of the calibration standard at a second temperature and determining change in the corresponding electrical property relative to the first measurement;
determining a temperature coefficient that describes relative change of the electrical property determined from the second measurement of the calibration standard referred to that determined from the first measurement;
determining a corrected electrical property of the calibration standard at a measurement temperature by using a value of the temperature coefficient applicable for the measurement temperature to the electrical property of the calibration standard determined at the first temperature; and
determining at least one error coefficient of the measurement unit from said corrected electrical property of the calibration standard, which describes relative change of the corrected electrical property of the calibration standard relative to the value measured at the measurement temperature.

2. Method according to claim 1, wherein the temperature coefficient is determined in frequency-dependent fashion.

3. Method according to claim 1, wherein a calibration standard is measured for measurement of low-frequency noise or for pulsed I/V measurement or for CV measurement or for HF measurement of scatter parameters.

4. Method according to claim 3, wherein a measurement of the low-frequency noise or a pulsed I/V measurement or a CV measurement is carried out by a source monitor unit.

5. Method according to claim 1, wherein several calibrations are conducted in which a calibration standard is formed on another calibration substrate.

6. A method for determination of an electrical property of an electronic component, comprising the following steps:
calibrating a measurement unit which serves to measure an electrical property of the electronic component according to claim 1;
measuring electrical measured quantity of the electronic component by said measurement unit at said measurement temperature;
clearing of the measurement quantity by using the error coefficient determined by calibration for the measurement temperature; and
determining the electrical property from the corrected measurement quantity.

7. Method according to claim 6, wherein the calibration and measurement of the electronic component occur in a frequency-dependent fashion.

8. Method according to claim 6, wherein measurement of a calibration standard occurs, and the standard is arranged together with the electronic component on a test substrate.

9. Method according to claim 6, wherein measurement of a calibration standard occurs, and the standard is arranged on a calibration substrate separate from a substrate of the electronic component.

10. Method according to claim 9, wherein the electronic component and the calibration substrate are held on two separate surfaces of a test device and temperature-controlled at the same measurement temperature by temperature control devices.

11. Method according to claim 9, wherein the electronic component and the calibration substrate are held on two separate support surfaces of a test device and calibration occurs at a calibration temperature deviating from the measurement temperature, comprising the following additional steps:
controlling temperature of the electronic component and the calibration substrate by at least one temperature control device at two temperatures deviating from each other, wherein the temperature of the electronic component is the measurement temperature and the temperature of the calibration substrate is the calibration temperature;
determining temperature difference between the calibration temperature and the measurement temperature; and
adjusting the corrected electric property determined for the calibration temperature of the calibration standard to the measurement temperature by using a value of the temperature coefficient applicable for the calibration temperature for the electrical property of the calibration standard determined at the first temperature.

12. Method according to claim 9, wherein the temperature coefficient is entered in a database.

13. Method according to claim 9, wherein the calibration standard is used for measurement of several electronic components under different environments.

14. Method according to claim 6, wherein the temperature coefficient is determined during measurement of several electronic components at least one additional time.

15. Method according to claim 14, wherein the error coefficient is also determined an additional time during measurement of several electronic components.

16. Method according to claim 6, wherein a measurement of low-frequency noise or a pulsed I/V measurement or a CV measurement is carried out by a source monitor unit
